(19) United States
(12) Patent Application Publication
(10) Pub. No.: US 2026/0150325 A1
(43) Pub. Date: May 28, 2026

(54) FIELD EFFECT TRANSISTOR

(71) Applicant: NTT, Inc., Tokyo (JP)

(72) Inventors: Taro Sasaki, Tokyo (JP); Takuya Tsutsumi, Tokyo (JP); Fumito Nakajima, Tokyo (JP)

(21) Appl. No.: 19/121,275

(22) PCT Filed: Oct. 20, 2022
(86) PCT No.: PCT/JP2022/039097

§ 371 Date: Apr. 15, 2025

(51) Int. Cl. H10D 30/47; H10D 30/00; H10D 62/10; H10D 64/27; H10D 86/00; H10W 20/43

(52) U.S. Cl. CPC H10D 30/4755; H10D 30/474; H10D 30/502; H10D 62/102; H10D 64/411; H10D 86/00; H10W 20/43

(57) ABSTRACT

An embodiment is a field effect transistor. The field effect transistor includes a gate electrode composed of a plurality of electrode wires, at least two of the plurality of electrode wires intersecting with each other, a feed terminal connected to one end of at least one of the plurality of electrode wires, and plurality of source electrodes and a plurality of drain electrodes arranged in respective regions defined at least in part by the plurality of electrode wires.

### CROSS-REFERENCE TO RELATED APPLICATIONS

This application is a national phase entry of PCT Application No. PCT/JP2022/039097, filed on Oct. 20, 2022, which application is hereby incorporated herein by reference.

### TECHNICAL FIELD

The present invention relates to a field effect transistor capable of performing a high-output and high-frequency operation.

### BACKGROUND

An electromagnetic wave (terahertz wave) having a frequency of 0.3 to 3.0 THz is expected to be applied to various applications such as the next-generation high-speed radio communications, non-destructive inspection by imaging using terahertz waves, security applications using transmission imaging, and material analysis using absorption spectra. Therefore, attention has been paid to electronic devices and integrated circuits which can cope with the terahertz frequency bands. Field effect transistors made of compound semiconductors with high electron mobility are used as an example of electronic devices with excellent high-frequency characteristics.

A basic configuration of a field effect transistor for high-frequency applications includes a channel layer, a source region (including an electrode), a drain region (including an electrode), and a gate electrode. When using an HEMT (High Electron Mobility Transistor) structure is used in this configuration, a buffer layer, a channel layer, and a barrier layer are stacked on a semiconductor substrate, an ohmic cap layer and an ohmic electrode, that is, source and drain electrodes, are formed thereon, and a gate electrode is formed between the source electrode and the drain electrode.

In the barrier layer, a carrier supply layer called a δ-doped layer is formed, and in the δ-doped layer, impurities are doped at a high concentration. Carriers generated by ionization of the impurities are accumulated in a channel layer having a band gap smaller than that of the barrier layer, to form a two-dimensional electron gas.

Since the two-dimensional electron gas in the channel layer is spatially separated from the ionized impurities by the barrier layer, the two-dimensional electron gas can travel between the source and the drain at a high speed without being affected by mobility deterioration due to impurity scattering.

Further, carrier injection from the ohmic electrode to the channel layer and carrier conduction from the channel layer to the ohmic electrode are facilitated. In other words, in order to reduce a source resistance Rs and a drain resistance Rd, the ohmic cap layer may be doped with impurities similarly to the carrier supply layer.

In the structure described above, a voltage is applied to the gate electrode to modulate a band structure immediately below the gate electrode, thereby controlling the concentration of the two-dimensional electron gas in the channel layer, and controlling the current amount flowing between the source and the drain. Therefore, in a configuration where the source electrode is grounded, by inputting a high-frequency signal to the gate electrode, an amplified high-frequency signal can be drawn out from the drain electrode.

In particular, when a field effect transistor for high-frequency applications is used to form a circuit such as a power amplifier which is important to increase the output, it is required to take out more outputs from the drain with respect to the high current driving capability of the field effect transistor itself, that is, an input to an arbitrary gate.

As shown in FIG. 10, a conventional field effect transistor 60_1 includes a source electrode 61, a gate electrode 63, a drain electrode 62, and a feed unit 64 in a mesa region 65, and a channel width W_{g0}. In general, a channel width W_{g} of a field effect transistor 60_2 is made longer (W_{g}>W_{g0}) in order to increase the driving current.

However, when a high-frequency signal is input from the feed unit 64 to one end of the gate electrode 63, the distance from the feed unit 64 to the other end of the gate electrode 63 becomes long, so that a gate resistance R_{g} typically increases linearly with respect to the channel width W_{g}. Here, the maximum transmission frequency fₘₐₓ, which is an important performance index used when estimating the applicable frequency of the field effect transistor for high-frequency applications, is expressed by the equation (1).

$$\begin{matrix}[ Math . 1 ] & \\ {f}_{max} = \frac{{f}_{t}}{2 \sqrt{( {R}_{i} + {R}_{s} + {R}_{g} ) {g}_{d , int} + ( 2 π {f}_{t} ) {R}_{g} {C}_{gd}}} & ( 1 )\end{matrix}$$

Here, fₜ is a current cut-off frequency, Rᵢ is a channel resistance, g_{d,int} is a drain conductance of a field effect transistor intrinsic region, and C_{gd} is a parasitic capacitance between the gate and the drain.

Therefore, the increase in R_{g} deteriorates the high-frequency characteristics of the transistor. This effect is particularly remarkable when the channel length L_{g} is shrunk to 100 nm or less.

Further, when the gate electrode 63 is made longer in one direction, the high frequency signal input from the feed unit 64 is not sufficiently transmitted to the other end of the gate electrode 63, so that the effect of making the gate width longer as designed cannot be obtained, and a region where the electric field from the gate electrode 63 does not act on the channel can be generated.

Further, as shown in FIG. 11, a driving current increased by a multi-channel structure in which a plurality of channel layers are stacked is disclosed (NPL 1). In A field effect transistor 70, an InAlAs buffer layer 72 is formed on a semi-insulating InP substrate 71, and a plurality of InGaAs channel layers 73 are stacked on the InAlAs buffer layer 72. An n-type InGaAs regrowth layer 74 is formed in the horizontal direction of the InGaAs channel layer 73, and a source electrode 75, a gate electrode 77 and a drain electrode 76 are formed on the surface. In this structure, a high driving current can be achieved without extending the channel width, by using the plurality of channel layers 73 stacked in the direction perpendicular to the substrate. That is, a high driving current can be achieved while suppressing an increase in gate resistance.

Further, as shown in FIG. 12, a high driving current by a multi-finger structure is disclosed (PTL 1). A field effect transistor 80 has a configuration in which a source electrode 82 and a drain electrode 83 are alternately arranged on an active region (channel layer) 81, a gate electrode 84 is arranged between each source electrode 82/drain electrode 83, and the source electrode 82, the drain electrode 83, and the gate electrode 84 are bundled into one to increase an effective channel width, and this configuration is applicable to a device having only a single channel layer. Since the plurality of gate electrodes 84 are connected in parallel, when designed with the same gate length and gate width, the increase of R_{g} can be suppressed as compared with the configuration of the field effect transistor 60_2 shown in FIG. 10.

### CITATION LIST

### Patent Literature

[PTL 1] Japanese Patent No. 6973670

### Non Patent Literature

[NPL 1] H.-B. Jo et al., “Lg=130 nm GAA MBCFETs with three-level stacked In0.53Ga0.47As nanosheets,” 2022 IEEE Symposium on VLSI Technology and Circuits, 2022, pp. 397-398.

### SUMMARY

However, in the multi-channel structure in which a plurality of channel layers are stacked, complicated processing such as etching of a sacrificial layer and formation of a MOS structure are involved because of its three-dimensional structure. Further, by introducing the MOS structure, it is necessary to newly consider the gate oxide film capacitance Cₒₓ and the defective capacitance Cᵢₜ caused by the defective level of the MOS interface, and even if a high driving current can be achieved, it is necessary to newly examine the gate oxide film capacitance Cₒₓ and the defective capacitance Cᵢₜ in order to improve the high frequency characteristics.

In addition, even when a multi-finger structure is adopted, it is necessary to perform either or both of extending the length of each finger and increasing the number of fingers in order to increase the driving current, increasing the footprint of an element and reducing the degree of integration. In general, the area occupied by an amplifier circuit such as a power amplifier is defined by a floor plan, and since the number of elements which can be integrated within a predetermined area is reduced in an element having a large footprint, an amplifier circuit having a desired output cannot be constructed. Even if the circuit area is not specified, since it is necessary to lay the wiring over a long distance in an element having a large footprint, transmission loss is increased and high output is limited.

### Solution to Problem

In order to solve the above problems, a field effect transistor according to embodiments of the present invention includes a gate electrode composed of a plurality of electrode wires intersecting each other, a plurality of source electrodes, a plurality of drain electrodes, and a feed unit connected to one end of at least one of the plurality of electrode wires, wherein the plurality of source electrodes and the plurality of drain electrodes are alternately arranged in respective regions separated by the plurality of electrode wires.

### Advantageous Effects

According to embodiments of the present invention, a field effect transistor capable of performing a high-output/high-frequency operation at a low gate resistance and high current driving capability can be provided.

### BRIEF DESCRIPTION OF THE DRAWINGS

FIG. 1A is a horizontal cross-sectional schematic diagram showing a configuration of a field effect transistor according to a first embodiment of the present invention.

FIG. 1B is a horizontal cross-sectional schematic diagram showing a configuration of a conventional field effect transistor.

FIG. 2A is a horizontal cross-sectional schematic diagram showing the configuration of the field effect transistor according to the first embodiment of the present invention.

FIG. 2B is a horizontal cross-sectional schematic diagram showing the configuration of the field effect transistor according to the first embodiment of the present invention.

FIG. 2C is a horizontal cross-sectional schematic diagram showing the configuration of a drain electrode of the field effect transistor according to the first embodiment of the present invention.

FIG. 2D is a cross-sectional schematic diagram taken along IID-IID′, showing the configuration of the field effect transistor according to the first embodiment of the present invention.

FIG. 2E is a cross-sectional schematic diagram taken along IIE-IIE′, showing the configuration of the field effect transistor according to the first embodiment of the present invention.

FIG. 3A is a vertical cross-sectional schematic diagram showing an example of the configuration of the field effect transistor according to the first embodiment of the present invention.

FIG. 3B is a vertical cross-sectional schematic diagram showing an example of the configuration of the field effect transistor according to the first embodiment of the present invention.

FIG. 4A is a diagram showing an equivalent circuit of the field effect transistor according to the first embodiment of the present invention.

FIG. 4B is a diagram showing an equivalent circuit of the conventional field effect transistor.

FIG. 5A is a horizontal cross-sectional schematic diagram showing a configuration of a field effect transistor according to a second embodiment of the present invention.

FIG. 5B is a horizontal cross-sectional schematic diagram showing an example of the configuration of the field effect transistor according to the second embodiment of the present invention.

FIG. 5C is a horizontal cross-sectional schematic diagram showing an example of the configuration of the field effect transistor according to the second embodiment of the present invention.

FIG. 6A is a horizontal cross-sectional schematic diagram showing a configuration of a field effect transistor according to a third embodiment of the present invention.

FIG. 6B is an enlarged cross-sectional schematic diagram taken along VIB-VIB′, showing the configuration of the field effect transistor according to the third embodiment of the present invention.

FIG. 6C is an enlarged cross-sectional schematic diagram taken along VIC-VIC′, showing the configuration of the field effect transistor according to the third embodiment of the present invention.

FIG. 7A is a horizontal cross-sectional schematic diagram showing a configuration of a field effect transistor according to a fourth embodiment of the present invention.

FIG. 7B is a horizontal cross-sectional schematic diagram showing a configuration of a source electrode of the field effect transistor according to the fourth embodiment of the present invention.

FIG. 7C is a horizontal cross-sectional schematic diagram showing a configuration of a drain electrode of the field effect transistor according to the fourth embodiment of the present invention.

FIG. 8 is a horizontal cross-sectional schematic diagram showing a configuration of a field effect transistor according to Modification 1 of the fourth embodiment of the present invention.

FIG. 9A is a horizontal cross-sectional schematic diagram showing a configuration of a field effect transistor according to Modification 2 of the fourth embodiment of the present invention.

FIG. 9B is a horizontal cross-sectional schematic diagram showing an example of the configuration of the field effect transistor according to Modification 2 of the fourth embodiment of the present invention.

FIG. 10 is a horizontal cross-sectional schematic diagram showing the configuration of the conventional field effect transistor.

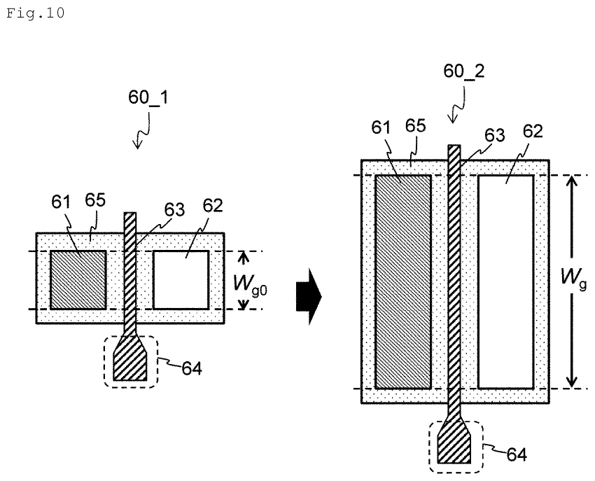

FIG. 11 is a bird's eye schematic diagram showing the configuration of the conventional field effect transistor.

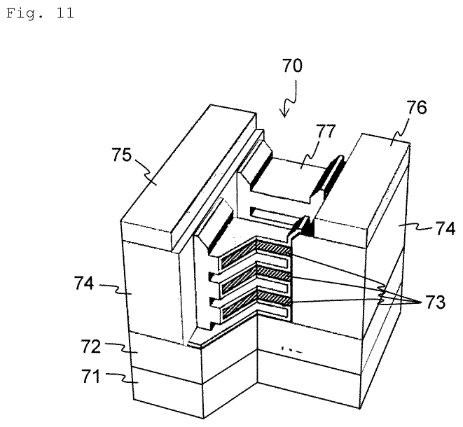

FIG. 12 is a top schematic diagram showing the configuration of the conventional field effect transistor.

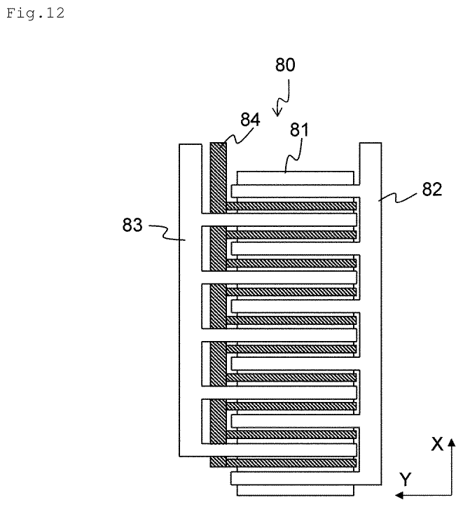

### DETAILED DESCRIPTION OF ILLUSTRATIVE EMBODIMENTS

### First Embodiment

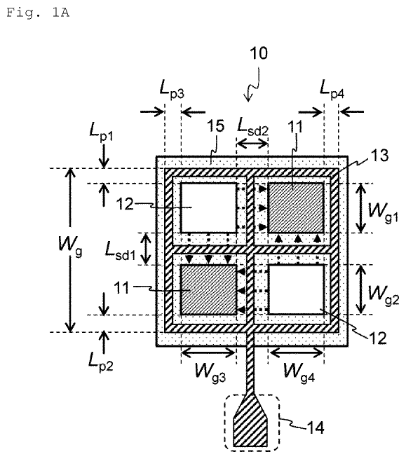

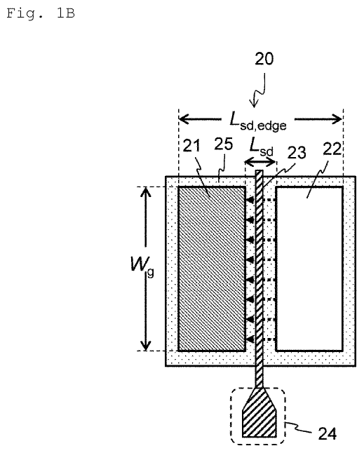

Hereinafter, a field effect transistor according to a first embodiment of the present invention will be described with reference to FIGS. 1A to 4B.

### <Configuration of Field Effect Transistor>

A field effect transistor 10 according to the present embodiment includes a layer composed of a semiconductor stacked structure, an electrode, and the like, the layer being formed by a substrate step (Front End of Line, FEOL) (hereinafter referred to as “FEOL layer”), and a wiring layer composed of wiring between electrodes and an insulating film (described later).

FIG. 1A is a cross-sectional schematic diagram of the FEOL layer of the field effect transistor 10 in a horizontal plane. For comparison, FIG. 1B shows a cross-sectional schematic diagram of the FEOL layer of an ordinary field effect transistor 20 in a horizontal plane. More specifically, each of the diagrams shows a cross-sectional schematic diagram of an ohmic cap layer (described later) of the FEOL layer on an upper surface.

As shown in FIG. 1B, the ordinary field effect transistor 20 includes, in the FEOL layer, a source electrode 21, a gate electrode 23, and a drain electrode 22 sequentially in a mesa region 25, wherein one end of the gate electrode 23 is provided with a feed unit 24. Here, the width of a channel sandwiched between the source electrode 21 and the drain electrode 22 (hereinafter referred to as “channel width”) is defined as W_{g}, and the distance between one end of the source electrode 21 and one end of the drain electrode 22 facing each other (hereinafter referred to as “source-drain distance”) is defined as L_{sd}, and the distance between the other end of the source electrode 21 and the other end of the drain electrode 22 is defined as L_{sd,edge}. The dotted arrows in the drawing indicate the directions in which a current flows.

As shown in FIG. 1A, in the field effect transistor 10 according to the present embodiment, two source electrodes 11 and two drain electrodes 12 are arranged alternately in two dimensions in a mesa region 15, and gate electrodes 13 are formed between and around the source electrodes 11 and the drain electrodes 12.

In other words, in the field effect transistor 10, the gate electrodes 13 have two electrode wires orthogonal to each other, and two source electrodes 11 and two drain electrodes 12 are alternately arranged in four regions divided by the two electrode wires. Further, the gate electrodes 13 also have electrode wirings in a region formed by the source electrodes 11 and the drain electrodes 12, that is, the outer periphery of the mesa region 15 (hereinafter referred to as “outer periphery portion”).

A feed unit 14 is provided at one end of the gate electrodes 13. An electric signal from the outside is input to the gate electrodes 13 from the feed unit 14.

Here, widths (channel widths) of channels sandwiched between the respective source electrodes 11 and drain electrodes 12 are defined as W_{g1}, W_{g2}, W_{g3}, W_{g4}, and the distances between the respective sources and drains are defined as L_{sd1} and L_{sd2}.

The width of a region for arranging the gate electrode 13 in the outer peripheral portion, that is, the length of the other end side (outer peripheral portion side) of the source electrode 11 and the drain electrode 12 shortened for inserting the gate electrode 13 in the outer peripheral portion, is defined as Lₚ₁, Lₚ₂, Lₚ₃, Lₚ₄. The suffix p is the initial character of the word “penalty.” Here, the dotted arrows in the diagram indicate the directions in which a current flows. In addition, “W_{g}” is shown in FIG. 1A for comparison with the channel width W_{g} of the ordinary field effect transistor 20.

In the field effect transistor 10, the true channel width W_{g}′ is expressed by the equation (2).

$$\begin{matrix}[ Math . 2 ] & \\ {W}_{g}^{′} = {W}_{g 1} + {W}_{g 2} + {W}_{g 3} + {W}_{g 4} & ( 2 )\end{matrix}$$

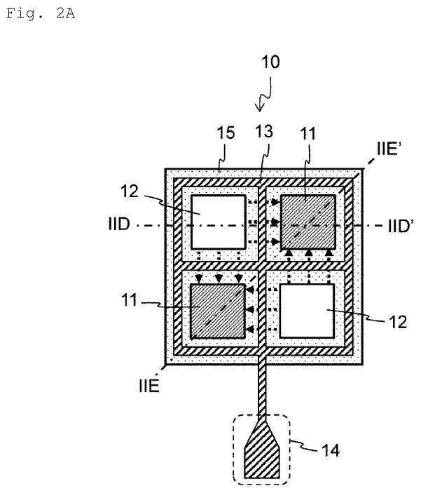

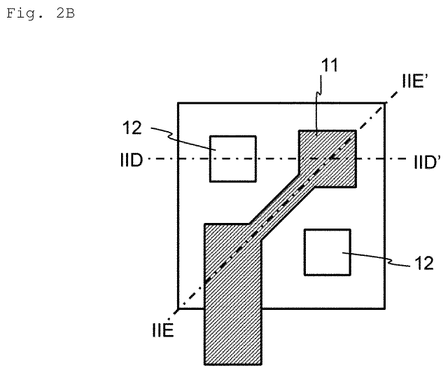

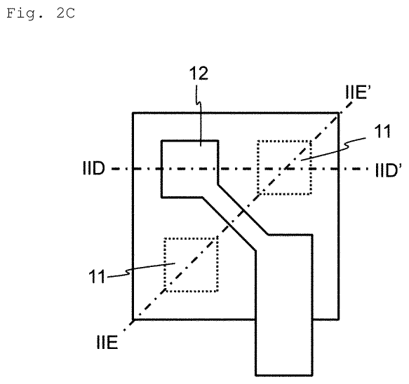

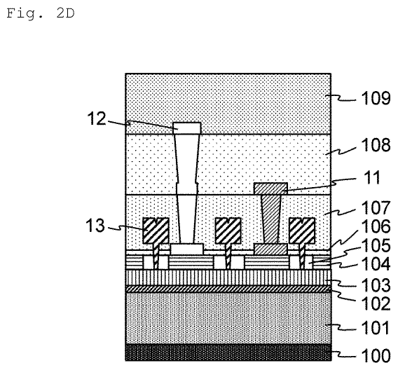

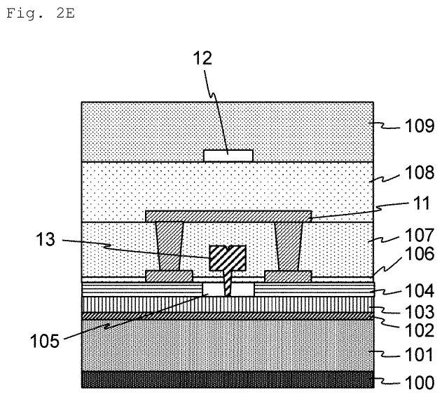

Next, a configuration of the wiring layer will be described with reference to FIGS. 2A to 2C. The wiring layer has an M1 layer and an M2 layer.

FIGS. 2A to 2C are cross-sectional schematic diagrams of the field effect transistor 10 according to the present embodiment, at a horizontal plane in the FEOL layer, a lower surface of the M1 layer, and a lower surface of the M2 layer. FIGS. 2D and 2E show a cross-sectional schematic diagram taken along IID-IID′ and a cross-sectional schematic diagram taken along IIE-IIE′, respectively, as an example of the configuration of the field effect transistor 10.

In the field effect transistor 10, the plurality of source electrodes 11 formed in a substrate step (FEOL) are electrically connected by the M1 layer (FIG. 2B), and the plurality of drain electrodes 12 are electrically connected by the M2 layer (FIG. 2C), obtaining integrated source electrodes 11 and drain electrodes 12. One end of each of the source electrodes 11 and one end of each of the drain electrodes 12 are pulled out to the outside of the mesa region 15 to function as a terminal electrically connected to the outside.

In this manner, a part of the source electrode 11, a part of the drain electrode 12, and a part of the gate electrode 13 intersect with each other three-dimensionally. As a result, the source electrodes 11, the drain electrodes 12, and the gate electrodes 13 can be pulled out without short-circuiting each other, that is, by being electrically insulated from each other.

As an example, the field effect transistor 10 has an InP-based HEMT structure as shown in FIGS. 2D and 2E, wherein an InAlAs buffer layer 101, an InGaAs channel layer 102, an InAlAs barrier layer 103 including a δ-doped layer, an InAlAs ohmic cap layer 104 doped at a high concentration, an InP etch stop layer 106, and an SiO₂ device protective film 107 are sequentially laminated on a semi-insulating InP substrate 100. Further, an M1 layer interlayer insulating film 108 made of SiO₂ and an M2 layer interlayer insulating film 109 made of SiO₂ are laminated. Here, the portion from the semi-insulating InP substrate 100 to the device protective film 107 is referred to as an FEOL layer.

The gate electrode 13 has a T-type gate structure in order to avoid an increase in gate resistance due to the skin effect, similarly to an ordinary field effect transistor for high-frequency applications.

In the gate electrode 13, a structure (stem) having a fine width at one end is formed so as to penetrate the ohmic cap layer 104 and the etch stop layer 106 and come into contact with the barrier layer 103. Here, the stem is disposed in a recess region 105 formed in a part of the ohmic cap layer 104 by etching with citric acid or the like.

The head at the other end of the gate electrode 13 is disposed in the device protective film 107.

Here, the dimensions of the stem and the head are limited to improve the performance by reducing the gate length L_{g}.

The source electrode 11 and the drain electrode 12 are formed so as to be in contact with the ohmic cap layer 104, and are pulled out to the M1 layer interlayer insulating film 108 through a hole structure (via hole or the like) of the device protective film 107. Further, the drain electrode 12 penetrates a hole structure (via hole or the like) of the M1 layer interlayer insulating film 108 and is pulled out to the M2 layer interlayer insulating film 109.

The channel layer 102 may be formed of InAs or a laminated film of InGaAs and InAs (InGaAs/InAs film).

The ohmic cap layer 104 may be formed of InGaAs doped at a high concentration or a laminated film of InAlAs and InGaAs doped at a high concentration (InAlAs/InGaAs film).

The device protective film 107, the M1 layer interlayer insulating film 108, and the M2 layer interlayer insulating film 109 may be oxide films other than SiO2, nitride films of Si3N4 or the like, or laminated films of an oxide film and a nitride film.

In addition, the structure other than the above-mentioned structure may be used, or a different layer structure which operates as a field effect transistor may be used.

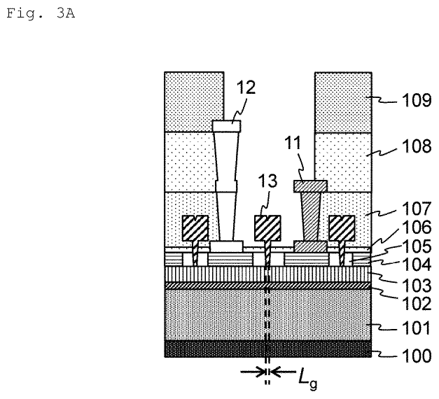

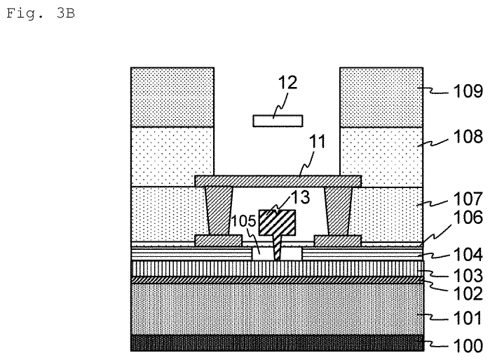

In the present embodiment, FIGS. 2D and 2E show an example in which the device protective film 107 is formed in the FEOL region and the interlayer insulating films 108 and 109 are formed in the M1 layer and the M2 layer. Here, in order to reduce parasitic capacitance components, a part of the device protective film 107 or interlayer insulating films 108, 109 is selectively etched as shown in FIGS. 3A and 3B, to form a bridge structure of the source electrode 11/drain electrode 12, that is, a so-called air bridge structure.

The air bridge structure is formed by, for example, after the M2 interlayer insulating film 109 is formed, forming a resist pattern in which a region to be a bridge portion of the source electrode and the drain electrode becomes an opening, irradiating plasma into the opening, and selectively etching the M2 interlayer insulating film 109 and M1 interlayer insulating film 108 of this region and the device protective film 107 of the FEOL region.

Here, the device protective film 107 and the interlayer insulating films 108, 109 are oxide films of SiO₂, nitride films of Si₃N₄, or laminated films of an oxide film and a nitride film. Examples of etching gas for these insulating films include SF₆, C₂F₆ and the like. Hydrofluoric acid may be used for etching the SiO₂. According to the air bridge structure, since the relative dielectric constant of the atmosphere is approximately 1, and the relative dielectric constant of a typical insulating film is approximately ⅓ to ⅕, the parasitic capacitance between the electrodes can be reduced.

In addition, a configuration of other wiring layers may be used as long as the source electrode 11 and the drain electrode 12 formed by FEOL are electrically connected and the source electrode, the drain electrode, and the gate electrode are not short-circuited.

### Advantageous Effects

Advantageous effects of the field effect transistor 10 according to the present embodiment will be described below. In order to simplify the description, as shown in FIGS. 1A and 1B, the channel width W_{g} of the ordinary field effect transistor 20 is set to be equal to the length of one side of the gate electrode 13 at the outer peripheral portion of the field effect transistor 10 according to the present embodiment. That is, W_{g}=Lₚ₁+W_{g1}+L_{sd1}+W_{g2}+Lₚ₂. In addition, the distances L_{sd,edge} between the other end of the source electrode 21 and the other end of the drain electrode 22 in the ordinary field effect transistor 20 are set to be equal to a sum of Lₚ₃, W_{g3}, L_{sd2}, W_{g4}, and Lₚ₄. That is, L_{sd,edge}=Lₚ₃+W_{g3}+L_{sd2}+W_{g4}+Lₚ₄.

First, the effect of increasing the driving current in the field effect transistor 10 according to the present embodiment will be described.

Here, as an example of the field effect transistor 10, W_{g}=L_{sd,edge}=10 μm, L_{sd}=L_{sd1}=L_{sd2}=2 μm, Lₚ₁=Lₚ₂=Lₚ₃=Lₚ₄=1 μm, and W_{g1}=W_{g2}=W_{g3}=W_{g4}=3 μm are set.

At this time, although the occupied areas of the field effect transistor 10 and the field effect transistor 20 are the same, the channel width of the field effect transistor 10 is 1.2 times the channel width of the field effect transistor 20 because W_{g}′=12 μm is obtained from the equation (2). Therefore, according to the field effect transistor 10, the driving current can be increased by a factor of 1.2.

In the field effect transistor 10, the channel width which increases as compared with the field effect transistor 20 is W_{g3}+W_{g4}, and the channel width which decreases is L_{sd1}+Lₚ₁+Lₚ₂.

Therefore, if the source electrode 11, the drain electrode 12, and the gate electrode 13 are designed so as to satisfy the equation (3), a high driving current can be obtained without changing the occupied area of the field effect transistor.

$$\begin{matrix}[ Math . 3 ] & \\ {W}_{g 3} + {W}_{g 4} > {L}_{sd 1} + {L}_{p 1} + {L}_{p 2} & ( 3 )\end{matrix}$$

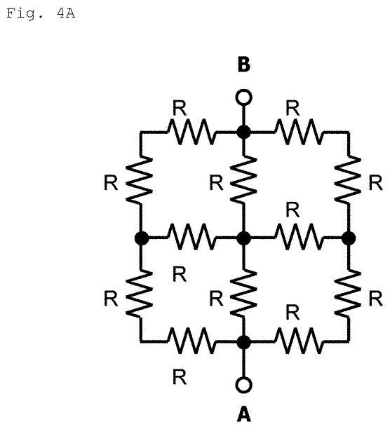

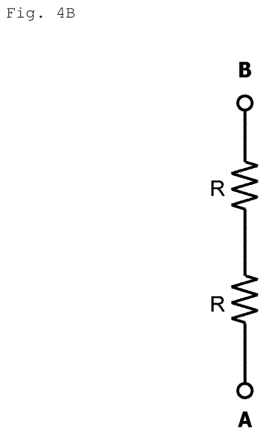

Next, effects of reducing the gate resistance in the field effect transistor 10 according to the present embodiment will be described with reference to FIGS. 4A and 4B.

FIGS. 4A and 4B show examples of equivalent circuits of the gate electrodes shown in FIGS. 1A and 1B, respectively.

As shown in FIG. 4B, the resistance of the gate electrode of the field effect transistor 20 shown in FIG. 1B is set to a resistance value 2R between A and B.

The equivalent circuit of the gate electrode in the field effect transistor 10 is obtained by forming a square gate electrode grid having the same material, structure, and size as those of the ordinary field effect transistor 20, as shown in FIG. 4A.

Thus, the resistance between A and B in the field effect transistor 10, that is, the gate resistance, is R.

As described above, according to the field effect transistor 10 according to the present embodiment, the gate resistance can be reduced to ½ without changing the occupied area of the element (field effect transistor).

The present embodiment has described an example in which the shape of the grid configuring the gate electrode is a square shape, but the shape is not limited thereto and may be a rectangular shape. Further, other shapes such as parallelogram, trapezoid, triangle, or the like may be used. Further, parameters such as dimensions can be arbitrarily designed in consideration of the integration degree, gate resistance reduction effect, high driving current, and parasitic capacitance between the gate electrode and the source/drain electrode.

Further, the structure of the field effect transistor according to the present embodiment can form various configurations only by changing the pattern of lithography, and can be easily applied to a manufacturing process where an existing epitaxial crystal wafer is used.

According to the present embodiment, low gate resistance and high driving current can be easily achieved at the same time by using existing manufacturing steps without changing the element area, and a field effect transistor capable of high output and high frequency operation can be realized.

### Second Embodiment

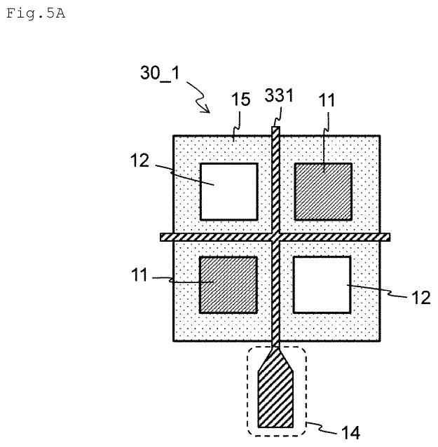

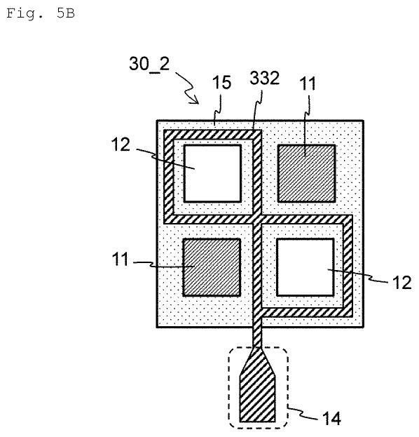

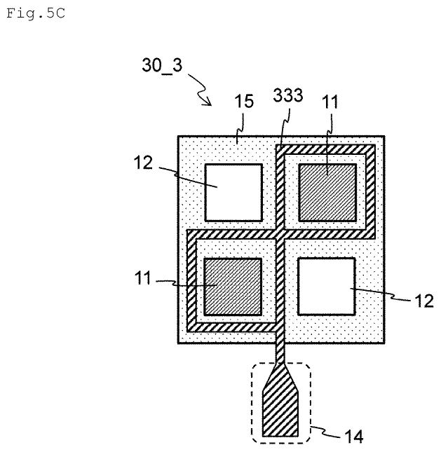

A field effect transistor according to a second embodiment of the present invention will be described with reference to FIGS. 5A to 5C.

### <Configuration of Field Effect Transistor>

As shown in FIG. 5A, a field effect transistor 30_1 according to the present embodiment includes a gate electrode 331 composed of two electrode wires arranged orthogonally between a source electrode 11 and a drain electrode 12. That is, the gate electrode 331 does not have electrode wires in the entire region of the outer peripheral portion. The other configurations are the same as those in the first embodiment.

According to the field effect transistor 30_1, compared to the configuration in the first embodiment, a source electrode and a drain electrode do not need to be reduced by Lₚ₁, Lₚ₂, Lₚ₃, Lₚ₄ in order to form a gate electrode (see FIG. 1A), so that the driving current can be made higher.

As an example, when W_{g}=L_{sd,edge}=10 μm and L_{sd}=L_{sd1}=L_{sd2}=2 μm, assuming that Lₚ₁ to Lₚ₄ are 0, since W_{g1}=W_{g2}=W_{g3}=W_{g4}=4 μm, W_{g}′=16 μm is obtained. Thus, the channel width of the field effect transistor 30_1 is 1.6 times the channel width of the field effect transistor 20. Therefore, according to the field effect transistor 30_1, the driving current can be increased by a factor of 1.6.

Thus, the field effect transistor 30_1 according to the present embodiment can achieve a higher driving current than the field effect transistor 10 according to the first embodiment.

Further, a capacitance C_{gs} between the gate electrode and the source electrode and a capacitance C_{gd} between the gate electrode and the drain electrode can be reduced by the small number of gate electrodes.

Next, in a field effect transistor 30_2 according to the present embodiment, a gate electrode 332 is arranged only around the drain electrode 12, as shown in FIG. 5B. That is, only the gate electrode around the source electrode 11 is removed. The other configurations are the same as tho A current gain cut-off frequency fₜ of the field effect transistor is expressed by the equation (4).se in the first embodiment.

A current gain cut-off frequency fₜ of the field effect transistor is expressed by the equation (4).

$$\begin{matrix}[ Math . 4 ] & \\ {f}_{t} = \frac{1}{2 π} \cdot \frac{{g}_{m , int}}{{C}_{gs} + {C}_{gd} + {g}_{m , int} ( {R}_{s} + {R}_{d} ) \cdot \{ {C}_{gd} + ( {C}_{gs} + {C}_{gd} ) \frac{{g}_{d , int}}{{g}_{m , int}} \}} & ( 4 )\end{matrix}$$

Here, g_{m,int} represents a transconductance of a field effect transistor intrinsic region.

Generally, since C_{gs} is approximately 5 to 10 times larger than C_{gd}, the current gain cut-off frequency fₜ may be deteriorated from the equation (4).

Therefore, according to the field effect transistor 30_2, since the gate electrode around the source electrode 11 is removed, C_{gs} can be selectively reduced, and the current gain cut-off frequency fₜ can be improved while securing the gate resistance reduction effect to a certain degree.

In a field effect transistor 30_3 according to the present embodiment, as shown in FIG. 5C, a gate electrode 333 is arranged only around the source electrode 11. That is, only the gate electrode around the drain electrode 12 is removed. The other configurations are the same as those in the first embodiment.

Here, C_{gd} is also referred to as a feedback capacitance, and is a parameter for determining fₘₐₓ as shown in the equation (1).

Therefore, according to the field effect transistor 30_3, since the gate electrode around the drain electrode 12 is removed, C_{gd} can be selectively reduced, and fₘₐₓ can be improved together with fₜ while securing the gate resistance reduction effect to a certain degree.

As described above, the field effect transistor according to the present embodiment does not have all or part of the gate electrode at the outer peripheral portion of the region formed by the source electrode and the drain electrode. In other words, the field effect transistor includes two gate electrodes arranged at least orthogonally between the source electrode and the drain electrode.

According to the present embodiment, by removing all or part of the gate electrode in the outer peripheral portion of the region formed by the source electrode and the drain electrode, a high driving current can be realized, and the improvement of fₜ and fₘₐₓ can be realized.

When a wafer layer structure for a circuit or device to which a field effect transistor is applied is formed in advance, desired performance can be realized by changing the structure of the gate electrode (including the peripheral structure) in the circuit or wafer layer structure.

### Third Embodiment

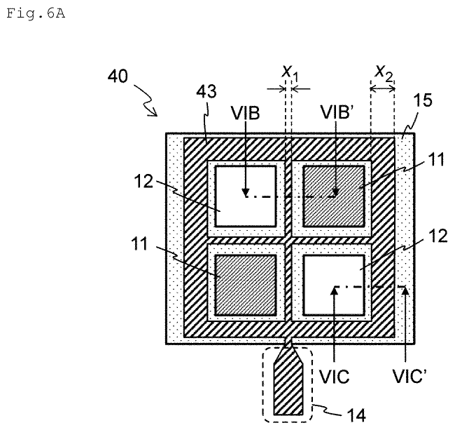

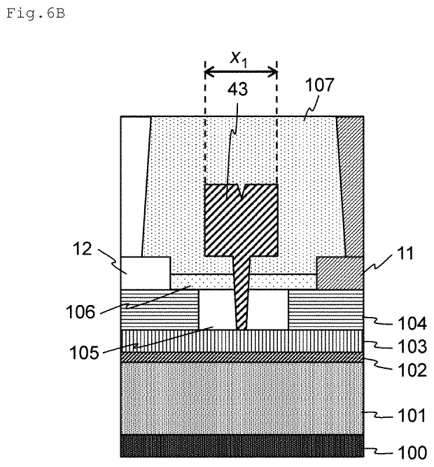

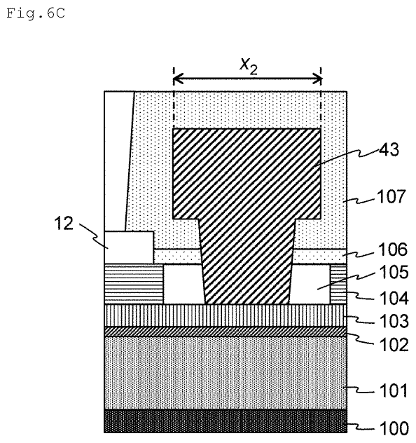

A field effect transistor according to a third embodiment of the present invention will be described with reference to FIGS. 6A to 6C.

### <Configuration of Field Effect Transistor>

FIG. 6A shows a cross-sectional schematic diagram of a FEOL layer of a field effect transistor 40 according to the present embodiment along a horizontal plane. According to the field effect transistor 40, in a gate electrode 43, an electrode wire width x₂ of a gate electrode on the outer periphery of a region formed by a source electrode 11 and a drain electrode 12 (hereinafter referred to as “outer peripheral gate electrode”) is wider than an electrode wire width x₁ of a gate electrode arranged between a source electrode and a drain electrode (hereinafter referred to as “inner gate electrode”). The other configurations are the same as those in the first embodiment. Here, the “electrode wire width” refers to the length in the direction perpendicular to the longitudinal direction of the outer peripheral gate electrode and the inner gate electrode, and refers to, for example, in the case of a T-type gate structure, the length of the head in the vertical direction.

FIGS. 6B and 6C show an enlarged cross-sectional diagram of an inner gate electrode region (cross-sectional diagram taken along VIB-VIB′) and an enlarged cross-sectional diagram of an outer peripheral gate electrode region (cross-sectional diagram taken along VIC-VIC′), respectively. In the field effect transistor 40, the lengths of the head and stem of the T-type gate structure in the outer peripheral gate electrode in the electrode wire width direction are longer than those of the head and stem of the inner gate electrode. Here, the cross-sectional area of the entire outer peripheral gate electrode may be larger than the cross-sectional area of the entire inner gate electrode.

In the field effect transistor 40, while the electrode wire width must be narrowed in order to control the current amount of the channel by the inner gate electrode, the electrode wire width can be widened because the outer gate electrode does not contribute to the current amount control of the channel.

Further, instead of the T-type gate structure in the outer peripheral gate electrode, an electrode having another structure such as a rectangular electrode having the same width as those of the head and stem may be used.

According to the present embodiment, since the electrode wire width of the outer peripheral gate electrode is wider than that of the first embodiment, the gate resistance can be reduced. As a result, a signal that is input to the feed unit can be propagated to the inner gate electrode after being propagated to the outer peripheral gate electrode at a high speed.

### Fourth Embodiment

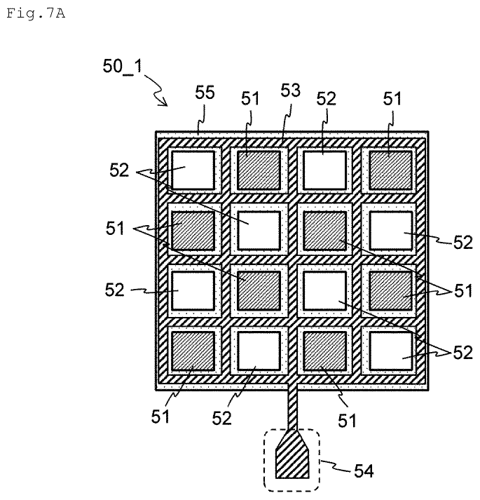

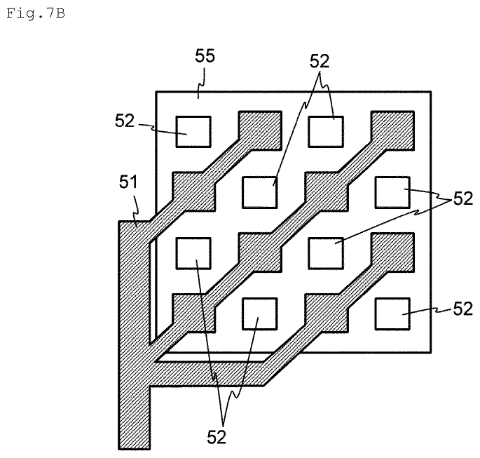

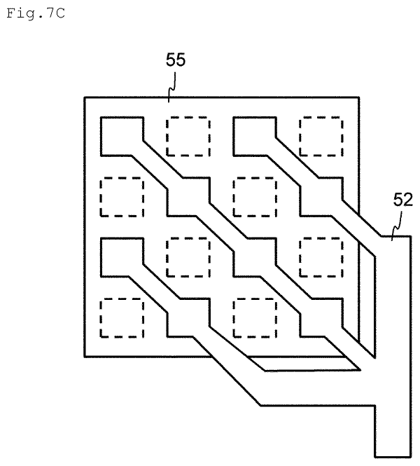

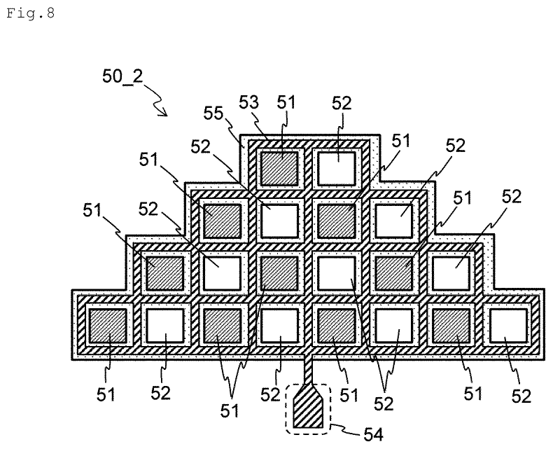

A field effect transistor according to a fourth embodiment of the present invention will be described with reference to FIGS. 7A to 7C and FIGS. 8A to 8C.

FIGS. 7A to 7C are cross-sectional schematic diagrams showing a field effect transistor 50_1 according to the present embodiment, on a horizontal plane (upper surface of the ohmic cap layer 104) in the FEOL layer, on a lower surface of the M1 layer, and on a lower surface of the M2 layer, respectively.

In the field effect transistor 50_1, as shown in FIG. 7A, source electrodes 51 and drain electrodes 52 are alternately arranged in a 4×4 array. A gate electrode 53 is disposed between each source electrode 51 and each drain electrode 52 and on an outer periphery thereof.

Further, the source electrodes 51 and the drain electrodes 52 are each electrically connected on the M1 layer and the M2 layer, as shown in FIGS. 7B and 7C.

The other configurations are the same as those in the first embodiment.

In the present embodiment, the connection structure shown in FIGS. 7B and 7C is shown as an example for the connection between the source electrodes and the drain electrodes, but the present invention is not limited thereto, and other connection structures may be employed as long as the gate electrodes, the source electrodes, and the drain electrodes are electrically isolated (insulated) from each other and the source electrodes and the drain electrodes can be electrically connected to each other.

According to the present embodiment, by expanding the configuration comprising the gate electrodes, the source electrodes, and the drain electrodes in an array, the channel width can be increased with high area efficiency, and the resistance of the channel on which carriers travel can be reduced. As a result, a high driving current can be realized.

### Modification Example 1

In a field effect transistor 50_2 according to Modification 1 of the present embodiment, as shown in FIG. 8, the source electrodes 51 and the drain electrodes 52 are alternately arranged in a fan-shaped plane having a feed unit 54 as the pivot of the fan-shaped plane, and the distances from the feed unit 54 to the source electrodes 51 and the drain electrodes 52 arranged on the outer periphery of the fan-shaped plane are substantially equal to each other. Here, it is preferable that the distances from the feed unit 54 to the source electrodes 51 or the drain electrodes 52 on the outer periphery are approximately several μm to 40 μm. When the distances are 1 mm or more, the influence related to high frequency transmission becomes remarkable.

According to the array-like electrode arrangement shown in the fourth embodiment (FIG. 7A), in some cases a phase shift of the input signal occurs between gate electrodes arranged at different positions (e.g., a left lower end and a left upper end, or a right lower end and a right upper end) depending on a frequency and a size of a device, or in some cases the input signal does not propagate to an electrode located far from the feed unit (e.g., a left upper end, a right upper end, or the like), and there is a possibility that on/off of the field effect transistor cannot be controlled as designed.

On the other hand, according to the electrode arrangement in this modification (FIG. 8), since the distances from the feed unit to the gate electrodes on the outer periphery are substantially equal, the field effect transistor can be turned on/off satisfactorily by propagating the input signal effectively without causing phase shift of the input signal.

### Modification 2

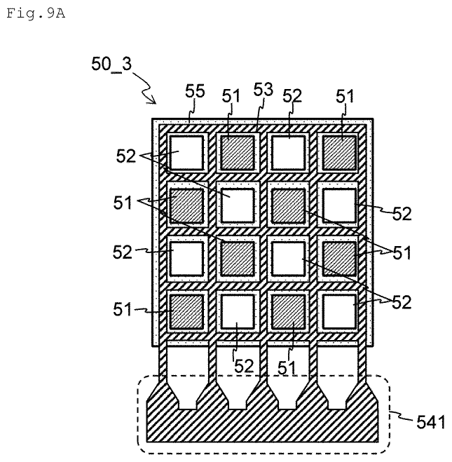

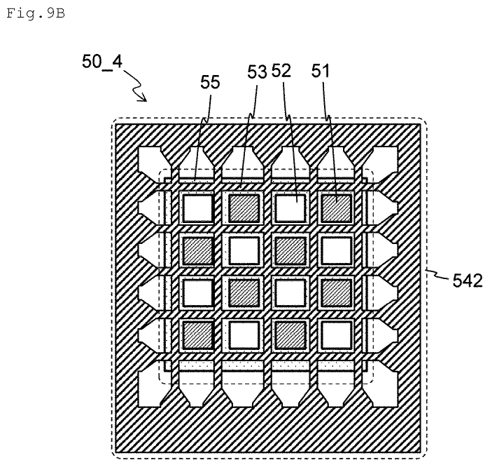

In a field effect transistor 50_3 according to Modification 2 of the present embodiment, as shown in FIG. 9A, source electrodes 51 and drain electrodes 52 are alternately arranged in a 4×4 array. A feed unit 541 is connected to and integrated with end portions of a plurality of electrode wires in the gate electrode 53, at a part of the outer peripheral portion of the mesa region 55.

Further, as in a field effect transistor 50_4 shown in FIG. 9B, a feed unit 542 may be connected to and integrated with end portions of the plurality of electrode wires in the gate electrode 53 over the entire outer peripheral portion of the mesa region 55.

According to this modification, the input signal can be effectively propagated.

Further, since the configuration of the source electrodes and the drain electrodes is not arranged in a multi-finger structure but arranged two-dimensionally, the channel width per unit footprint can be made long, and gate resistance can be reduced.

In this modification, the electrical connection structure of the feed unit is not limited to the structure shown in FIGS. 9A and 9B, but may have a configuration in which the feed unit is connected to and integrated with the end portions of a plurality of electrode wires in the gate electrode.

Although the embodiments of the present invention have illustrated an example in which the gate electrode is not formed outside the mesa region (except for FIG. 5A), the present invention is not limited thereto. When the channel layer and the ohmic cap layer are subjected to side etching or the like and these layers and the gate electrode are most likely not electrically connected to each other, the gate electrode may be formed outside the mesa region. In the side etching, the channel layer and the ohmic cap layer are selectively etched to a predetermined depth from a side wall of the mesa region by an acid solution or the like, thereby forming a recess portion in the channel layer and the ohmic cap layer on the side wall.

In the case where the gate electrode is formed only on the inside of the mesa region, the side etching step is not required in the manufacturing process, so that forming the gate electrode only on the inside of the mesa region is easier than an existing process where the gate electrode is formed outside the mesa region. When the gate electrode is formed only on the inside of the mesa region, the risk that the gate electrode is electrically connected to the source electrodes or drain electrodes due to lack of side etching can be avoided.

Although the embodiments of the present invention have illustrated an example of arranging two source electrodes and two drain electrodes, the present invention is not limited thereto. At least one of a source electrode and a drain electrode may be plural.

Furthermore, although the embodiments of the present invention have illustrated an example in which the shape of the source electrodes or the drain electrodes is square, the shape may be a polygon such as a triangle or pentagon, or a circle or oval.

Although the embodiments of the present invention have illustrated an example in which the electrode wires of the gate electrodes are arranged so as to be orthogonal to each other, the present invention is not limited thereto. The gate electrodes may be arranged so as to intersect with each other at a predetermined angle according to the shape and the number of the source electrodes or the drain electrodes. The source electrodes, the drain electrodes, and the gate electrodes may be arranged so as to satisfy a desired parasitic capacitance and a desired gate resistance reduction effect.

For example, one equilateral triangular source electrode and two equilateral triangular drain electrodes may be arranged, and a gate electrode composed of electrode wires intersecting at 60° between the respective electrodes and electrode wires of the outer peripheral portion may be arranged.

The embodiments of the present invention have illustrated an example in which a T-type gate structure is used for the gate electrodes, but the present invention is not limited thereto, and electrodes with other structures may be used.

Although the embodiments of the present invention have illustrated an example in which the HEMT structure is used for the configuration of the field effect transistor, the present invention is not limited thereto, and a MOSFET (metal-oxide-semiconductor field effect transistor) structure or a MESFET (metal-semiconductor field effect transistor) structure may be used, and an FET structure having a channel layer, a source region (including an electrode), a drain region (including an electrode), and a gate electrode may be used.

Although the embodiments of the present invention have illustrated an example in which InGaAs, InAlAs, or the like on the InP substrate is used as a material for the field effect transistor, the present invention is not limited thereto. Other semiconductor materials such as AlGaAs on the GaAs substrate, Si/SiGe on the Si substrate, and Si-based materials may be used.

Although the embodiments of the present invention have illustrated examples of structures, dimensions, materials, and the like of each component in configurations of the field effect transistor, the manufacturing method thereof, and the like, the present invention is not limited thereto. Any modifications can be made as long as the modifications exert the functions of the field effect transistor and exhibit its effect.

### INDUSTRIAL APPLICABILITY

The embodiments of the present invention can be applied to a next-generation high-speed communication system using a high frequency, a non-destructive inspection device, a security technology, a material analysis technology, and the like.

### REFERENCE SIGNS LIST

10 Field effect transistor
11 Source electrode
12 Drain electrode
13 Gate electrode
14 Feed unit

1-8. (canceled)

9. A field effect transistor, comprising:
a gate electrode composed of a plurality of electrode wires, at least two of the plurality of electrode wires intersecting with each other;
a feed terminal connected to one end of at least one of the plurality of electrode wires; and
a plurality of source electrodes and a plurality of drain electrodes arranged in respective regions defined at least in part by the plurality of electrode wires.

10. The field effect transistor according to claim 9, comprising:
a FEOL layer including the gate electrode;
a first layer arranged on the FEOL layer; and
a second layer arranged on the first layer,
wherein the plurality of source electrodes are electrically connected to each other on the first layer or the second layer,
the plurality of drain electrodes are electrically connected to each other on the first layer or the second layer, and
a part of the gate electrode, a part of the source electrodes, and a part of the drain electrodes intersect with each other three-dimensionally and are electrically insulated from each other.

11. The field effect transistor according to claim 9, wherein the plurality of electrode wires of the gate electrode are arranged in at least a part of an outer peripheral portion of a region constituted by the plurality of source electrodes and the plurality of drain electrodes.

12. The field effect transistor according to claim 11, wherein an electrode wire width of the gate electrode arranged in the outer peripheral portion is wider than an electrode wire width of the gate electrode arranged between the plurality of source electrodes and the plurality of drain electrodes.

13. The field effect transistor according to claim 9, wherein the plurality of electrode wires of the gate electrode are arranged only around the plurality of source electrodes.

14. The field effect transistor according to claim 9, wherein the plurality of electrode wires of the gate electrode are arranged only around the plurality of drain electrodes.

15. The field effect transistor according to claim 9, wherein the feed terminal is a single terminal, and
the plurality of source electrodes and the plurality of drain electrodes are arranged in a fan shape having the feed terminal as a pivot of the fan shape.

16. The field effect transistor according to claim 9, wherein the feed terminal is connected to and integrated with end portions of the plurality of electrode wires.

17. The field effect transistor according to claim 15, wherein distances from the feed terminal to each of the plurality of source electrodes and the plurality of drain electrodes arranged on an outer periphery of the fan shape are substantially equal.

18. The field effect transistor according to claim 9, wherein the plurality of electrode wires of the gate electrode form a grid pattern.

19. The field effect transistor according to claim 9, further comprising an air bridge structure between at least some of the plurality of source electrodes or between at least some of the plurality of drain electrodes.

20. The field effect transistor according to claim 9, wherein the gate electrode, the plurality of source electrodes, and the plurality of drain electrodes are formed on a high electron mobility transistor (HEMT) structure.

21. The field effect transistor according to claim 20, wherein the HEMT structure comprises an InP substrate, an InAlAs buffer layer, an InGaAs channel layer, and an InAlAs barrier layer including a δ-doped layer.

22. The field effect transistor according to claim 9, wherein the plurality of source electrodes and the plurality of drain electrodes are formed on an ohmic cap layer.

23. The field effect transistor according to claim 9, wherein a channel width of the field effect transistor is greater than a length of one side of an outer periphery of a region formed by the plurality of source electrodes and the plurality of drain electrodes.

24. A high electron mobility transistor (HEMT), comprising:
a semiconductor substrate;
a buffer layer on the semiconductor substrate;
a channel layer on the buffer layer;
a barrier layer on the channel layer;
a plurality of source electrodes and a plurality of drain electrodes arranged alternately in a planar array on the barrier layer;
a gate electrode structure comprising a plurality of intersecting wires, the intersecting wires separating the plurality of source electrodes and the plurality of drain electrodes; and
a feed terminal connected to the gate electrode structure.

25. The high electron mobility transistor of claim 24, wherein the semiconductor substrate is an InP substrate, the buffer layer is an InAlAs buffer layer, the channel layer is an InGaAs channel layer, and the barrier layer is an InAlAs barrier layer including a δ-doped layer.

26. A high-frequency amplifier circuit, comprising:
at least one field effect transistor, the field effect transistor including:
a plurality of source electrodes and a plurality of drain electrodes in a planar arrangement;
a gate electrode comprising intersecting wires forming enclosed regions, wherein each of the enclosed regions contains one of the plurality of source electrodes or one of the plurality of drain electrodes;
a feed terminal connected to the gate electrode;
an input matching network connected to the gate electrode; and
an output matching network connected to the plurality of drain electrodes.

27. The high-frequency amplifier circuit of claim 26, wherein the intersecting wires of the gate electrode form a grid pattern, and the plurality of source electrodes and the plurality of drain electrodes are arranged in an array pattern within the grid pattern.
